(19) United States
(12) Patent Application Publication
(10) Pub. No.: US 2018/0094166 A1
(43) Pub. Date: Apr. 5, 2018

(54) CMP POLISHING COMPOSITION COMPRISING POSITIVE AND NEGATIVE SILICA PARTICLES

(71) Applicant: Rohm and Haas Electronic Materials CMP Holdings, Inc., Newark, DE (US)

(72) Inventors: Yi Guo, Newark, DE (US); David Mosley, Lafayette Hill, PA (US)

(21) Appl. No.: 15/281,873

(22) Filed: Sep. 30, 2016

(51) Int. Cl. C09G 1/02; H01L 21/306; H01L 21/3105

(52) U.S. Cl. CPC C09G 1/02; H01L 21/31051; H01L 21/30625

(57) ABSTRACT

The present invention provides aqueous chemical mechanical planarization (CMP) polishing compositions comprising a positively charged silica particle composition with from 3 to 20 wt. % in total, based on the total silica particle solids in the CMP polishing composition, of one or more negatively charged silica particle compositions in which the silica particles have a z-average particle size as determined by Dynamic Light Scattering (DLS) of from 5 to 50 nm. The z-average particle size (DLS) ratio of the silica particles in the positively charged silica particle composition to that of the silica particles in the one or more negatively charged silica particle compositions ranges from 1:1 to 5:1 or, preferably, from 5:4 to 3:1. The compositions enable improved polishing of dielectric or oxide substrates and are shelf stable for at least 7 days at room temperature.

The present invention relates to aqueous chemical mechanical planarization (CMP) polishing compositions comprising a mixture of a positively charged silica particle composition and a negatively charged silica composition, particularly, wherein the positively charged silica particles are aminosilane group containing silica particles and the average particle size of the positively charged silica composition is greater than the average particle size of the negatively charged silica composition, as well as to methods of making the same.

Previously, the mixing of abrasive particles has sometimes increased the polish rate of a SiO₂ or oxide containing substrate surface in the chemical mechanical planarization CMP process or otherwise improve that process.

Previously, those using aminosilanes in aqueous silica CMP polishing compositions have always had shipping stability issues. Silica particles typically gel or aggregate in the pH range of 4 to 7.5, especially in concentrates with silica particles above 20% by weight of the solution. Adding silane to the CMP polishing compositions to help with polishing can add a positive charge so less silica is needed; however, adding an aminosilane to silica CMP polishing compositions creates stability issues at a pH of 4 to 7, the pH at which positively charged silica particles have high removal rates for the polishing of silicon dioxide surfaces. Addition of aminosilane can reduce the electrostatic repulsion of the silica surfaces in silica containing CMP polishing compositions, thereby decreasing their colloidal stability.

United States patent publication no. US20150267082, to Grumbine et al. discloses mixtures of two, a first and a second, silica particles, the first particle of which is a colloidal silica having an average particle size of from 10 to 130 nm and has a permanent positive charge of at least 10 mV and the second particle of which has a neutral or non-permanent positive charge and an average particle size of from 80 to 200 nm. The first silica particle is treated with an aminosilane and the second silica particle may be treated with a quaternary amine compound. Grumbine fails to disclose a detailed method for treating the first silica particle with the aminosilane. Further, the compositions disclosed in Grumbine fail to provide improved polishing of dielectric substrates, such as tetraethoxysilane (TEOS).

The present inventors have endeavored to solve the problem of providing aqueous silica CMP polishing compositions that improve the CMP polishing composition of dielectric substrates, such as interlayer dielectrics (ILD).

### STATEMENT OF THE INVENTION

1. In accordance with the present invention, aqueous chemical mechanical planarization (CMP) polishing compositions comprise a mixture of a positively charged silica particle composition with in total from 3 to 20 wt. %, or from 3 to 17.5 wt. %, preferably from 5 to 12 wt. %, or, more preferably, from 7 to 10 wt. %, based on the total silica particle solids in the CMP polishing composition, of one or more negatively charged silica particle compositions in which the negatively charged silica particles have prior to forming the mixture a z-average particle size as determined by Dynamic Light Scattering (DLS) of from 5 to 50 nm wherein prior to forming the mixture the z-average particle size (DLS) ratio of the silica particles in the positively charged silica particle composition to that of the silica particles in the one or more negatively charged silica particle compositions ranges from 1:1 to 5:1 or, preferably, from 5:4 to 3:1.

2. The aqueous CMP polishing compositions as set forth in item 1, above, wherein the positively charged silica particle composition comprises silica particles containing one or more aminosilane chosen from an aminosilane containing an tertiary amine group, such as N,N-(diethylaminomethyl)triethoxysilane, an aminosilane containing at least one secondary amine group, such as N-aminoethylaminopropyl trimethoxysilane (AEAPS) or N-ethylaminoethylaminopropyl trimethoxysilane (DEAPS aka DETAPS), or mixtures thereof, preferably, containing a tertiary amine group.

3. The aqueous CMP polishing compositions as set forth in any one of items 1 or 2, above, wherein the zeta potential of the positively charged silica particle composition ranges from 10 to 35 mV at a pH 3.5, or, preferably, from 15 to 30 mV.

4. The aqueous CMP polishing compositions as set forth in any one of items 1, 2 or 3, above, wherein the composition has a pH of from 3.5 to 5 or, preferably, a pH of from 4.0 to 4.7.

5. The aqueous CMP polishing compositions as set forth in any one of items 1, 2, 3 or 4, above, wherein the composition comprises a total silica particle solids content of from 1 to 30 wt. %, or, preferably, wherein the composition is a concentrate having a total silica particle solids content of from 15 to 25 wt. %, or, more preferably, from 18 to 24 wt. %.

6. The aqueous CMP polishing compositions as set forth in any one of items 1 to 5, above, wherein the composition comprises aggregate silica particles created by the mixing of two types of oppositely charged silica particles.

7. The aqueous CMP polishing compositions as set forth in any one of items 1 to 6, above, wherein the z-average particle size as determined by Dynamic Light Scattering (DLS) of the silica particles in the positively charged silica particle composition ranges from 25 to 150 nm, preferably from 30 to 70 nm, prior to forming the mixture.

8. In accordance with a separate aspect of the present invention, methods of making an aqueous chemical mechanical planarization (CMP) polishing compositions comprise adjusting the pH of an aqueous aminosilane to from 3 to 8, preferably, from 3.5 to 4.5 with a strong acid, preferably, nitric acid, allowing it to sit for a period of from 5 to 600 minutes or, preferably, from 5 to 120 minutes to hydrolyze any silicate bonds in the aminosilane and form a hydrolyzed aqueous aminosilane and adjusting the pH of the hydrolyzed aqueous aminosilane to from 3 to 5, preferably, from 3.5 to 4.5 with a strong acid; separately, adjusting the pH of a first aqueous silica slurry having a z-average particle size as determined by Dynamic Light Scattering (DLS) of from 25 to 150 nm, preferably from 30 to 70 nm, to a pH of from 3.5 to 5, preferably from 4.0 to 4.7 with a strong acid, preferably, nitric acid to form a first aqueous silica slurry; combining the first aqueous silica slurry and the hydrolyzed aqueous aminosilane, with shearing to form an aqueous positively charged silica particle composition; separately, adjusting the pH of one or more negatively charged aqueous silica slurry having a z-average particle size (DLS) of from 5 to 50 nm to from 3.5 to 5, preferably from 4.0 to 4.7 with a strong acid, preferably, nitric acid, to form a second aqueous silica slurry composition; and combining the aqueous positively charged silica composition with the second aqueous silica slurry composition in a total amount of the second aqueous silica slurry composition of from 3 to 20 wt. %, or, from 3 to 17.5 wt. %, or, preferably, from 5 to 12 wt. %, or, more preferably, from 7 to 10 wt. %, based on the total weight of silica particle solids in the CMP polishing composition, wherein the ratio of the z-average particle size of the silica in the first aqueous silica slurry to the z-average particle size of the silica in the second aqueous silica slurry composition ranges from 1:1 to 5:1 or, preferably, from 5:4 to 3:1.

9. In accordance with the methods of making an aqueous CMP polishing composition as in item 8 of the present invention, wherein the aqueous aminosilane comprises one or more aminosilane chosen from an aminosilane containing an tertiary amine group, such as N,N-(diethylaminomethyl)triethoxysilane, an aminosilane containing at least one secondary amine group, such as N-aminoethylaminopropyl trimethoxysilane (AEAPS) or N-ethylaminoethylaminopropyl trimethoxysilane (DEAPS aka DETAPS), or mixtures thereof.

10. In accordance with the methods of making an aqueous CMP polishing composition as in any one of items 8 or 9 of the present invention, above, wherein the composition is a concentrate and the total silica particle solids of the aqueous chemical mechanical planarization (CMP) polishing composition ranges from 15 to 25 wt. % or, preferably, from 18 to 24 wt. %.

11. In accordance with the methods of making an aqueous CMP polishing composition as in any one of items 8, 9 or 10 of the present invention, above, the methods further comprising diluting the aqueous CMP polishing composition to a total silica particle solids of from 1 to 10 wt. %, based on the total weight of the composition.

Unless otherwise indicated, conditions of temperature and pressure are ambient temperature and standard pressure. All ranges recited are inclusive and combinable.

Unless otherwise indicated, any term containing parentheses refers, alternatively, to the whole term as if no parentheses were present and the term without them, and combinations of each alternative. Thus, the term “(poly)amine” refers to amine, polyamine, or mixtures thereof.

All ranges are inclusive and combinable. For example, the term “a range of 50 to 3000 cPs, or 100 or more cPs” would include each of 50 to 100 cPs, 50 to 3000 cPs and 100 to 3000 cPs.

As used herein, the term “ASTM” refers to publications of ASTM International, West Conshohocken, Pa.

As used herein, the term “ISO” refers to publications of the International Organization for Standardization, Geneva, CH.

As used herein, the term “hard base” refers to metal hydroxides, including alkali metal hydroxides, such as NaOH, KOH, or CsOH.

As used herein, the term “silica particle solids” means, for a given composition, the total amount of positively charged silica particles, plus the total amount of negatively charged silica particles, plus the total amount of any other silica particles, including anything with which any of those particles are treated.

As used herein, the term “solids” means any material other than water or ammonia that does not volatilize in use conditions, no matter what its physical state. Thus, liquid silanes or additives that do not volatilize in use conditions are considered “solids”.

As used herein, the term “strong acid” refers to protic acids having a pKa of 2 or less, such as inorganic acids like sulfuric or nitric acid.

As used herein, the term “use conditions” means the temperature and pressure at which a given composition is used, including increases in temperature and pressure during use.

As used herein, the term “wt. %” stands for weight percent.

As used herein, the term “z-average particle size (DLS)” means the z-Average particle size of the indicated composition as measured by Dynamic Light Scattering (DLS) using a Malvern Zetasizer device (Malvern Instruments, Malvern, UK) calibrated per manufacturers recommendations. The z-Avg particle size is the intensity-weighted harmonic mean size, which is a diameter, as calculated by ISO method ISO13321:1996 or its newer pendant ISO22412:2008. Particle size measurements were made on the concentrated slurries or diluted slurries as described in the examples. Unless otherwise indicated, particle size measurements were made on slurry compositions diluted to 1% w/w silica particle solids and having a pH ranging from 3.5 to 4.5.

As used herein, the term “zeta potential” refers to the electrokinetic potential of a given composition as measured by a Malvern Zetasizer instrument (Malvern Instruments, Malvern, UK). Unless otherwise indicated, All zeta potential measurements were made on given slurry compositions at the pH and solids content listed in the examples, such as concentrates. The reported value was taken from an averaged measurement of zeta values using >20 acquisitions taken by the instrument for each indicated composition. The concentration of silica particles, ionic strength, and pH of the measurement solution all affect the zeta potential.

The present inventors have surprisingly found that mixing a composition of positively charged silica particles with a small amount of a composition of negatively charged silica particles that are smaller or equal in size relative to the positively charged silica particles provides enhanced polish rates on silica (TEOS) wafers without significantly impacting the positive zeta potential of the positively charged silica particles. In addition, the present inventors have found that adding a small amount of the smaller negatively charged silica particles (z-average (DLS) of from 5 to 50 nm) can substantially improve polish rates of aminosilane-group containing silica particles. The aqueous compositions containing the mixture of the silica particles remain colloidally stable (no visible sediment) at room temperature for 7 days. Such compositions exhibit both a minimal decrease in zeta potential (zeta potential decreased less than 30%) and a small increase in average particle size as determined via light scattering. An aggregation process may occur in the mixtures of the present invention to produce agglomerates that have both negative and positive silica particles therein.

Simple mixing of a negative silica particle with a positive silica particle creates compositions which may contain aggregates or secondary particles, such as positively charged silica particles having negatively charged silica particles on their surface, having improved polishing effect in the pH range of 3.5 to 5 than a known mixture of two particle compositions (such as described in Grumbine). In addition, in accordance with the present invention, just one silica particle is modified or surface treated to form a positively charged silica composition. Accordingly, the present invention allows one to vary silica particle aggregation at any time after modifying the silica particles by combining the aminosilane treated or modified positively charged silica composition with negatively charged silica particles. The present invention thereby enables the formulation of customized slurry properties for any specific application at the point of distribution or use, as opposed to at the point of manufacturing.

In accordance with the hydrolyzed aqueous aminosilane of the present invention, such compositions are allowed to sit so as to hydrolyze any silicate bonds formed on storage. For aminosilanes containing one or more secondary amine groups, the pH of such aqueous aminosilanes is maintained at from 7 to 8 for from 5 to 600 minutes, such as for 5 to 120 minutes, before the pH is adjusted to from 3.5 to 5 with a strong acid. As aminosilanes having one or more secondary amine groups are not preferred, the preferred method of making a hydrolyzed aqueous aminosilane comprises adjusting the pH of the aqueous aminosilane of the present invention, for example, one having one or more tertiary amino group, to a pH of from 3.5 to 4.5 and allowing it to sit for from 5 to 600 or from 5 to 120 minutes.

To insure colloidal stability of the aqueous CMP polishing compositions of the present invention, the compositions have a pH ranging from 3.5 to 5 or, preferably, from 4.0 to 4.7. The compositions tend to lose their stability above the desired pH range.

In accordance with the present invention, the positively charged silica particles are formed by mixing silica particles in an aqueous silica slurry with an hydrolyzed aqueous aminosilane composition. Upon mixing, the pH of the aqueous silica slurry and of the hydrolyzed aqueous aminosilane composition ranges from 3 to 5. The silica particles in the positively charged silica particle composition will thus contain the aminosilane; the positively charged silica particles, for example, will contain the aminosilane bound to or associated with the silica particle surface.

In accordance with the present invention, the aminosilanes in the positively charged silica particles are used in amounts such that more aminosilane is used with smaller silica particles and less aminosilane is used with larger silica particles.

Suitable aminosilanes for use in making the aminosilane group containing positively charge silica particles of the present invention are tertiary amine group and secondary amine group containing aminosilanes. Such aminosilanes are more readily hydrolyzed at the desired pH range of the aqueous silica CMP polishing compositions of the present invention (pH 3.5 to 5) than are primary amine group containing aminosilanes.

Preferably, the secondary amine group containing aminosilanes of the present invention perform best when the one or more negatively charged silica particle compositions are present in total amounts of from 3 to 7.5 wt. %, based on the total weight of silica particle solids in the composition.

Preferably, in accordance with the CMP polishing compositions of the present invention, total amount of the aminosilane used ranges from 3 to 40 millimoles per Kg of silica particle solids (mM/Kg silica), or, more preferably, from 3 to 20 (mM/Kg silica).

The composition of the present invention is intended for dielectric polishing, such as interlayer dielectrics (ILD).

### EXAMPLES

The following examples illustrate the various features of the present invention.

The following materials were used in the Examples that follow:

Slurry A: Klebosol™ B25 silica (Merck KgAA, Darmstadt, Germany) an aqueous slurry of silica made from Na silicate (water glass), solids content of 30% w/w, having a pH 7.7-7.8 and an average particle size of (density gradient centrifugation) 38 nm;

Slurry B: Klebosol™ B12 silica (Merck KgAA, Darmstadt, Germany) an aqueous slurry of silica made from Na silicate (water glass), solids content of 30% w/w, having a pH 7.7-7.8 and an average particle size of (density gradient centrifugation) 25 nm.

Aminosilane 1: N,N-(diethylaminomethyl)triethoxysilane (DEAMS) containing a tertiary amino group, 98%, (Gelest Inc., Morrisville, Pa.);

Aminosilane 2: N-(2-aminoethyl)-3-aminopropyltrimethoxysilane (AEAPS) containing a secondary amine group, 98%, (Gelest Inc.)

The following abbreviations were used in the Examples that follow:

POU: Point of use; RR: Removal rate.

The following test methods were used in the Examples that follow:

Initial pH: The “Initial pH” of compositions tested was that pH measured one time from the indicated concentrate compositions disclosed below at the time they were made.

pH at POU: The pH at point of use (pH at POU) was that measured during removal rate testing after dilution of the indicated concentrate compositions with water to the indicated solids content.

Removal Rate: Removal rate testing from polishing on the indicated substrate was performed using the indicated polisher, such as a Strasbaugh 6EC 200 mm wafer polisher or “6EC RR” (San Luis Obispo, Calif.) or an Applied Materials Mirra™ 200 mm polishing machine or “Mirra RR” (Applied Materials, Santa Clara, Calif.), as indicated, at the indicated downforce and table and carrier revolution rates (rpm), and with the indicated CMP polishing pad and abrasive slurry at a 200 mL/min abrasive slurry flow rate. A Diagrid™ AD3BG-150855 diamond pad conditioner (Kinik Company, Taiwan) was used to condition the polishing pad. The CMP polishing pad was broken in with the pad conditioner using a down force of 6.35 kg (14.0 lb) for 20 minutes and was then further conditioned prior to polishing using a down force of 4.1 kg (9 lb) for 10 minutes. The CMP polishing pad was further conditioned in situ during polishing at 10 sweeps/min from 4.3 to 23.5 cm from the center of the polishing pad with a down force of 4.1 kg (9 lb). The removal rates were determined by measuring the film thickness before and after polishing using a KLA-Tencor FX200 metrology tool (KLA Tencor, Milpitas, Calif.) using a 49 point spiral scan with a 3 mm edge exclusion.

Z-Average Particle Size: The Z-Average particle size of the indicated composition was measured by Dynamic Light Scattering (DLS) using a Malvern Zetasizer device (Malvern Instruments, Malvern, UK) calibrated per manufacturers recommendations and in the manner defined above with concentrations defined in the examples.

Zeta Potential: Zeta potential of the indicated compositions was measured by a Malvern Zetasizer instrument in the manner defined above with concentrations and pH as defined in the examples.

### Examples 1 to 6

Slurry A particles diluted to 24.8% w/w solids in water were adjusted to pH 4.25 using nitric acid. Where indicated in Table 1, below, a 3.7% w/w solution of pre-hydrolyzed (N,N-diethylaminomethyl) triethoxysilane (Aminosilane 1) in water at pH 4.25 was added to the Slurry A particles to make the resulting slurry composition 0.005 molal (5 mm) in silane. The pH of the resulting positively charged silica particle slurry was maintained between 4.1 and 4.25 for 3 hrs, and the content of silica at this point was ˜24 wt. % of the total wet composition. After 3 hrs, the indicated amount of the indicated silica slurry of (negatively charged) particles was added to the formulations with sufficient water to keep the overall particle concentration diluted to 24 wt. %. Before addition of the negatively charged silica particles, the pH of the positively charged silica particle composition and the negative particle composition was set to 4.1. Example 6 had no added negatively charged silica particles and was a comparative example; the Slurry A particles in Example 6 were combined with the hydrolyzed aqueous aminosilane as above.

The zeta potentials of the slurries in Example 1-6 were measured on the concentrated slurries, after aging for 12 days, at the indicated pH (aged pH) in Table 1. The particle sizes in Examples 1-6 were measured on the aged slurries diluted to approximately 1 wt % silica using deionized water. The zeta potential of the positively charged silica particle compositions (Slurry A+aminosilane) before addition of the negatively charged silica particle composition but after aminosilane addition is expected to be similar to Example 6 so approximately +17 mV. Zeta potential measurements of Slurry A (no aminosilane) at pH 4.0 gave −21 mV. Zeta potential measurements of Slurry B (no aminosilane) at pH 4.0 gave −15 mV. The 24 wt. % slurry compositions or slurry concentrates were stored at room temperature for 12 days before polishing testing. The slurry concentrates were diluted to 4% for polishing with the Strasbaugh 6EC to obtain the removal rate of TEOS material, and the pH after dilution was adjusted to 4.75 with potassium hydroxide. A Strasbaugh 6EC 200 mm wafer polisher was run at 20.7/34.5 kPa with a table speed of 93 rpm, and a substrate carrier speed of 87 rpm. To test performance, tetraethoxysilane (TEOS) wafers were polished at a flow rate of 200 mL/min. Unless otherwise indicated, an IC1010™ pad from Dow Electronic Materials was used. The 1010™ pad is a urethane pad 80 mils thick with a shore D hardness of 57. (The Dow Chemical Company, Midland, Mich., (Dow)) was used to polish the substrate. The results are shown in Table 1, below.

TABLE 1
Performance of Various Aqueous Slurry Compositions

| | 6EC | 6EC | | | | Z-Ave | Aged Zeta |
|---|---|---|---|---|---|---|---|
| | RR¹ | RR¹ | | | | Particle | potential of |
| EXAMPLE and | 20.7 kPa | 34.5 kPa | | | | size by | concentrate |
| COMP (wt. %) | (Å/min) | (Å/min) | Initial pH | Aged pH | pH at POU | DLS (nm) | (mV) |
| 1 95% Slurry A² + | 2520 | 3624 | 4.1 | 4.35 | 4.75 | 28.8 | 16.5 |
| 5% Slurry B | | | | | | | |
| 2 90% Slurry² A + | 2606 | 3632 | 4.12 | 4.38 | 4.75 | 33.5 | 15.2 |
| 10% Slurry B | | | | | | | |
| 3 87.5% Slurry² A + | 2559 | 3609 | 4.11 | 4.4 | 4.75 | 40.4 | 12.4 |
| 12.5% Slurry B | | | | | | | |
| 4 91.7% Slurry A² + | 2441 | 3458 | 4.13 | 4.36 | 4.75 | 27.0 | 15.5 |
| 8.3% Slurry A | | | | | | | |
| 5 83.3% Slurry A² + | 2401 | 3402 | 4.11 | 4.33 | 4.75 | 28.1 | 14.0 |
| 16.7% Slurry A | | | | | | | |
| 6* 100% Slurry A² | 2375 | 3368 | 4.15 | 4.39 | 4.75 | 26.3 | 17.0 |

¹The wt. % silica (negatively charged particles at POU was 4 wt. %, based on the total solids in the compositions tested;
²Slurry A was modified to form a positively charged silica particle composition in all examples; however in examples 4 and 5 a smaller amount of unmodified slurry A particles were added in place of Slurry B;
*Denotes comparative example.

As shown in Table 1, above, mixing in the smaller, negatively charged silica particles with positively charged silica in Examples 1, 2 and 3 gave a significant boost to the removal rate. Further, compositions containing limited amounts of the negatively charged particles in Examples 1 and 2 appear to perform better than the Example 3 inventive composition containing 12.5 wt. % of the negatively charged silica particles. In Examples 1 to 3, addition of larger amounts of the smaller slurry B negatively charged particles led to an increased Z-average particle size, which reveals a tendency toward aggregation of the positive and negative particles. In Examples 4 and 5, the ratio of the z-average particle size of the silica particles in the positively charged silica particle composition to that of the silica particles in the positively charged silica particle was 1:1 and was not preferred; the performance of the compositions in those Examples was improved significantly but not as much as in Examples 1, 2 and 3.

### Example 7

Testing was performed to evaluate the change in Z-Average particle size over time to determine the aggregation rate, if any, between the positively and negatively charged silica particles after mixing. Slurry A particles diluted to ˜24% w/w solids in water were adjusted to pH 4.25 using nitric acid. A 3.7% w/w solution of pre-hydrolyzed (N,N-diethylaminomethyl)triethoxysilane in water at pH 4.25 was added to the particles to make the solution 0.005 molal (5 mm) in silane. The pH of the solution was maintained between 4.15 and 4.25 for 1 hr, and the total wt. % of silica at this point was 24%. The pH was then adjusted to 4.0 using nitric acid and the compositions were stored for 16 hrs before any of the positively charged and negatively charged particles were mixed and tested. On the day of testing, Slurry B at 30 wt. % solids was adjusted to pH 4.5 using nitric acid. Then, the Slurry A and the Slurry B particles were mixed in the ratio 22.2% w/w solids Slurry A−Aminosilane 1 to 1.8% w/w solids Slurry B directly in a Malvern DLS cuvette (Malvern Instruments). The measurements of particle size were conducted at a total silica concentration of 24%. The measurements of particle size were acquired in front-scattering mode every 10 seconds, and the initial measurement of Slurry A−Aminosilane 1 particles was conducted for 3 time points before the Slurry B negatively charged particles were added at the 30 second mark. To check pH effects, the Slurry A−Aminosilane 1 aliquot (bulk of solution) was adjusted to pH 4.1, 4.5, and 4.8 using KOH before the measurements began. The results are summarized in Table 2, below, as the average of 3 data points before the addition and the average of 3 data points 60 seconds after the addition. The total test time followed by DLS was 20 minutes.

TABLE 2
Effect of Mixing Positively and Negatively
Charged Silica Particles on Aggregation

| Starting pH of | | |
|---|---|---|
| Slurry A- | Average hydrodynamic | Average hydrodynamic Z- |
| Aminosilane 1 | Z-avg radius (nm) 1^{st} 30 | avg radius (nm) 90-110 |
| concentrate | sec | sec |
| 4.1 | 26.86 +/− 0.36 | 27.98 +/− 0.45 |
| 4.5 | 26.80 +/− 0.26 | 28.99 +/− 0.30 |
| 4.8 | 27.65 +/− 0.30 | 29.53 +/− 0.37 |

As shown in Table 2, above, a small degree of aggregation occurs within one minute. No subsequent growth in particle size by DLS was observed in minutes 1-20 of the test. Accordingly, in the inventive pH range of 4-5, aggregation was fast but controlled: No gel formation or large particles are formed as detected by dynamic light scattering.

### Examples 8 to 10

110.43 grams of DI water was mixed with 2800 grams of Slurry A. The pH of the solution was reduced to 4.25 using nitric acid. To this mixture was added 89.6 grams of pre-hydrolyzed Aminosilane 2 solution. The hydrolyzed Aminosilane 2 solution contained 2.22% w/w of the AEAPS monomer and was allowed to hydrolyze at pH of 8 for 30 minutes and then adjusted to pH 4.25 using nitric acid. After each of 10 minutes and 60 minutes of reaction between the Aminosilane 2 and silica, the pH was re-adjusted to 4.2 using KOH and/or nitric acid. After 60 minutes of stirring, the Slurry A−Aminosilane 2 concentrate was stored overnight at room temperature. About 16 hrs after the synthesis, the pH of the concentrate was reduced to pH 3.5 using nitric acid, and the concentrate was stored for 2 months at room temperature before conducting the mixing experiment with Slurry B colloidal silica. For Slurry B, the silica was first acidified to pH 4.1 using nitric acid. Then the Slurry B was added to the concentrated Slurry A−Aminosilane 2, prepared above, with stirring. Next, water was added to obtain the indicated dilution for polishing (POU), followed by a final adjustment with KOH to achieve the indicated polishing pH. The Strasbaugh 6EC 200 mm wafer polisher was run at 20.7 kPa with a table speed of 93 rpm, carrier speed of 87 rpm. TEOS wafers were polished at a flow rate of 200 mL/min. An IC1010™ pad from Dow Electronic Materials was used. The 1010™ pad is a urethane pad 80 mils thick with a shore D hardness of 57. (The Dow Chemical Company, Midland, Mich., (Dow)) was used to polish the substrate. The results are shown in Table 3, below.

TABLE 3
Removal Rate with Aminosilane 2

| | TEOS RR | | |
|---|---|---|---|
| Example and | 6EC | pH at POU | Wt. % Silica |
| Formulation (by | 20.7 kPa | during | Solids at |
| wt. silica solids) | (ang/min) | polish | POU |
| 9* | 2192 | 4.75 | 4 |
| 100% Slurry A- | | | |
| Aminosilane 2 | | | |
| 10 | 2292 | 4.75 | 4 |
| 95% Slurry A- | | | |
| Aminosilane 2 + | | | |
| 5% Slurry B | | | |
| 11* | 2148 | 4.75 | 4 |
| 90% Slurry A- | | | |
| Aminosilane 2 + | | | |
| 10% Slurry B | | | |

In Example 10, a significant removal rate boost was achieved with addition of 5 wt. % solids of Slurry B. In Comparative Example 11, too much of Slurry B reduced the removal rate.

1. An aqueous chemical mechanical planarization (CMP) polishing composition comprising a mixture of a positively charged silica particle composition with from 3 to 20 wt. % in total, based on the total silica particle solids in the CMP polishing composition, of one or more negatively charged silica particle compositions in which the negatively charged silica particles prior to forming the mixture have a z-average particle size as determined by Dynamic Light Scattering (DLS) of from 5 to 50 nm, and wherein, prior to forming the mixture, the z-average particle size (DLS) ratio of the silica particles in the positively charged silica particle composition to that of the silica particles in the one or more negatively charged silica particle compositions ranges from 1:1 to 5:1, the composition comprising aggregate silica particles of the positively charged and negatively charged silica particles.

2. The aqueous CMP polishing composition as claimed in claim 1, wherein the total amount of the one or more negatively charged silica particle compositions ranges from 5 to 12 wt. %, based on the total silica particle solids in the CMP polishing composition.

3. The aqueous CMP polishing composition as claimed in claim 1, wherein the z-average particle size (DLS) ratio of the silica particles in the positively charged silica particle composition to the silica particles in the one or more negatively charged silica particle compositions ranges from 5:4 to 3:1.

4. The aqueous CMP polishing composition as claimed in claim 1, wherein the positively charged silica particle composition comprises silica particles containing one or more aminosilane chosen from an aminosilane containing a tertiary amine group, an aminosilane containing at least one secondary amine group, or mixtures thereof.

5. The aqueous CMP polishing composition as claimed in claim 4, wherein the aminosilane contains a tertiary amine group.

6. The aqueous CMP polishing composition as claimed in claim 1, wherein the zeta potential of the positively charged silica particle composition ranges from 10 to 35 mV at a pH 3.5.

7. The aqueous CMP polishing composition as claimed in claim 1, wherein the composition has a pH of from 3.5 to 5.

8. The aqueous CMP polishing composition as claimed in claim 1, wherein the composition comprises a total silica particle solids content of from 1 to 30 wt. %.

9. The aqueous CMP polishing composition as claimed in claim 8, wherein the composition is a concentrate and comprises a total silica particles solids content of from 15 to 25 wt. %.

10. A method of making an aqueous chemical mechanical planarization (CMP) polishing composition comprising:
adjusting the pH of an aqueous aminosilane to from 3 to 8 with a strong acid, allowing it to sit for a period of from 5 to 600 minutes to hydrolyze any silicate bonds in the aminosilane and form a hydrolyzed aqueous aminosilane, and, if needed, adjusting the pH of the hydrolyzed aqueous aminosilane to from 3 to 5;
separately, adjusting the pH of a first aqueous silica slurry having a z-average particle size as determined by Dynamic Light Scattering (DLS) of from 25 to 150 nm to a pH of from 3 to 5 with a strong acid to form a first aqueous silica slurry;
combining the first aqueous silica slurry and the hydrolyzed aqueous aminosilane, with shearing to form an aqueous positively charged silica particle composition;
separately, adjusting the pH of one or more second aqueous silica slurries having a z-average particle size (DLS) of from 5 to 50 nm to from 3 to 5 with a strong acid to form a second aqueous slurry composition; and,
combining the aqueous positively charged silica composition with the second aqueous silica slurry composition in a total amount of the second aqueous silica slurry composition of from 3 to 20 wt. %, based on the total weight of silica particle solids in the CMP polishing composition, wherein the ratio of the z-average particle size of the silica in the first aqueous silica slurry to the z-average particle size of the silica in the second aqueous silica slurry composition ranges from 1:1 to 5:1.
